(19) United States
(12) Patent Application Publication
(10) Pub. No.: US 2018/0254340 A1
(43) Pub. Date: Sep. 6, 2018

(54) TUNNEL FINFET WITH SELF-ALIGNED GATE

(71) Applicant: GLOBALFOUNDRIES INC., GRAND CAYMAN (KY)

(72) Inventors: EDWARD J. NOWAK, SHELBURNE, VT (US); RAM ASRA, CLIFTON PARK, NY (US); MURALI V R M KOTA, SHRUB OAK, NY (US)

(73) Assignee: GLOBALFOUNDRIES INC., GRAND CAYMAN (KY)

(21) Appl. No.: 15/969,226

(22) Filed: May 2, 2018

Related U.S. Application Data
(62) Division of application No. 15/354,047, filed on Nov. 17, 2016.

(51) Int. Cl. H01L 29/78; H01L 29/66; H01L 29/51; H01L 29/10; H01L 29/08; H01L 21/311

(52) U.S. Cl. CPC H01L 29/785; H01L 29/66795; H01L 21/31111; H01L 29/1095; H01L 29/1033; H01L 29/0847; H01L 29/7801; H01L 29/7835; H01L 29/0865; H01L 29/1083; H01L 29/517; H01L 29/66659; H01L 29/0882; H01L 29/66477; H01L 29/518; H01L 29/0895; H01L 29/512

(57) ABSTRACT

Structures and methods for a tunnel field-effect transistor (TFET). The TFET includes a gate electrode, a source region having a first conductivity type, a drain region having a second conductivity type opposite from the first conductivity type, and a dielectric layer separating the gate electrode from the source region and the drain region. The dielectric layer provides a channel region between the source region and the drain region. The channel region includes a relatively thin tunnel dielectric between the source region and the gate electrode and a relatively thick drift dielectric between the gate electrode and the drain region.

### CROSS-REFERENCE TO RELATED APPLICATIONS

The present invention claims the benefit under 35 U.S.C. § 120 as a divisional of U.S. patent application Ser. No. 15/354,047 filed on Nov. 17, 2016, the entire teachings of which are incorporated herein by reference.

### BACKGROUND

The present disclosure relates to semiconductor devices and, more particularly, to structures and methods for forming tunnel field-effect transistors (TFET).

Nanoscale devices show increased short channel effects, which lead to increased leakage currents. TFETs with channel and source/drain regions formed in silicon, typically suffer from low on-currents, a drawback related to the large resistance of the tunnel barrier. In TFETs, both the on-current and the off-current are determined by band-to-band tunneling from the valence band to the conduction band of the semiconductor material. Controlling the current injection from source to channel through band-to-band tunneling leads to reduced leakage. Tunneling currents are limited by tunnel barrier height, width, and tunneling area. Various methods have been proposed to enhance the on-current, such as using a small band-gap source material to reduce tunneling barrier height and width, and also making tunnel FETs on narrow-band gap channel materials. Even though using narrow band-gap materials enhances the on-current, it has disadvantages.

No process flow has been disclosed for manufacturing TFET devices having a high on-current (Ion) and a low leakage current (Ioff).

### SUMMARY

There is a need for a TFET device and a manufacturing process for such TFET device that enables band-to-band tunneling in the source region. This results in very high fields at the junction edge and a parasitic gate-induced drain leakage (GIDL) current from source to drain. This results in a degraded leakage floor. According to structures and methods herein, a two-part gate dielectric is formed with a thin portion self-aligned to the source enabling low tunnel voltage and a thick portion self-aligned to the drain resulting in low GIDL current.

In other words, a relatively thin dielectric is provided between the source region and the gate to generate channel carriers by tunneling. A thicker dielectric is provided for the drift region, but the alignment of the thin region allows the source carriers to efficiently reach the drift region.

According to an exemplary tunnel field-effect transistor (TFET) herein, the TFET includes a gate electrode, a source region having a first conductivity type, a drain region having a second conductivity type opposite from the first conductivity type, and a dielectric layer separating the gate electrode from the source region and drain region. The dielectric layer provides a channel region between the source region and the drain region. The channel region includes a tunnel dielectric between the source region and the gate electrode and a drift dielectric between the gate electrode and the drain region. The tunnel dielectric is thinner than the drift dielectric.

According to another exemplary tunnel field-effect transistor (TFET) herein, the TFET includes a gate electrode, a source region, a drain region, the source region and drain region being of opposite conductivity types, and a dielectric layer separating the gate electrode from the source region and drain region. The dielectric layer is made of two parts. The first part includes a tunnel gate dielectric and the second part includes a drift dielectric. The tunnel dielectric is relatively thin between the source region and the gate electrode, compared to the drift dielectric, and the drift dielectric is relatively thick between the gate electrode and the drain region, compared to the tunnel dielectric.

According to exemplary method of manufacturing a tunnel field-effect transistor (TFET), a drift layer is formed over a substrate. A first portion of the substrate is doped to form a source region in the substrate. A tunnel dielectric layer is formed over the source region and drift layer. A gate electrode is formed over the tunnel dielectric. A portion of the tunnel dielectric layer and gate electrode is etched away down to the substrate. A second portion of the substrate is doped to form a drain region in the substrate.

### BRIEF DESCRIPTION OF THE DRAWINGS

The foregoing and other exemplary purposes, aspects and advantages will be better understood from the following detailed description of exemplary embodiments herein with reference to the drawings, which are not necessarily drawn to scale and in which:

FIGS. 1-10 are schematic diagrams of a sectional view of semiconductor structure in fabricating a TFET device according to structures and methods herein;

FIG. 11 is a plan view of a TFET device according to structures and methods herein; and

FIG. 12 is a flow diagram illustrating embodiments herein.

### DETAILED DESCRIPTION

As mentioned above, TFETs with channel and source/drain regions formed in silicon, typically suffer from low on-currents, a drawback related to the large resistance of the tunnel barrier. In TFETs, both the on-current and the off-current are determined by band-to-band tunneling from the valence band to the conduction band of the semiconductor material. Controlling the current injection from source to channel through band-to-band tunneling leads to reduced leakage. Tunneling currents are limited by tunnel barrier height, width, and tunneling area.

In view of the foregoing, disclosed herein are TFET devices that include a gate electrode, a source region having a first conductivity type, a drain region having a second conductivity type opposite from the first conductivity type, and a dielectric layer separating the gate electrode from the source region and the drain region. The dielectric layer provides a channel region between the source region and the drain region. The channel region includes a relatively thin tunnel dielectric between the source region and the gate electrode and a relatively thick drift dielectric between the gate electrode and the drain region. Specifically, a two-part gate dielectric is formed with a thin portion self-aligned to the source enabling low tunnel voltage and a thick portion self-aligned to the drain enabling low current resulting from gate-induced drain leakage (GIDL) current. Gate-induced drain leakage is a leakage mechanism in FETs due to large field effect in the drain junction.

For purposes herein, a “semiconductor” is a material or structure that may include an implanted impurity that allows the material to sometimes be a conductor and sometimes be an insulator, based on electron and hole carrier concentration. As used herein, “implantation processes” can take any appropriate form (whether now known or developed in the future) and can comprise, for example, ion implantation, etc.

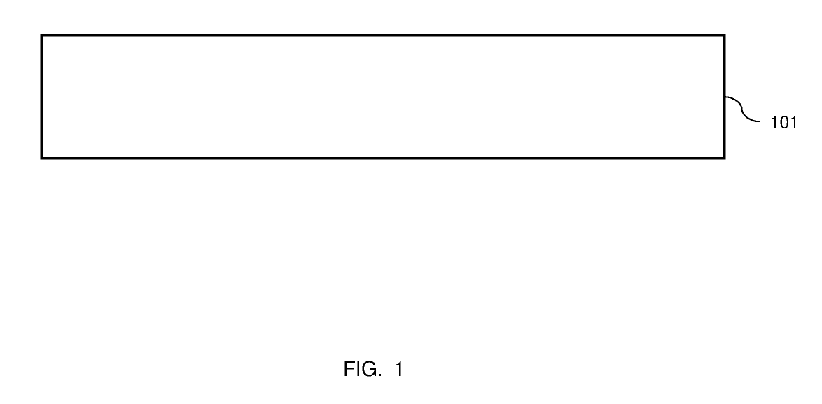

FIGS. 1-10 illustrate the processing steps for forming a tunnel field-effect transistor (TFET), according to devices herein. In FIG. 1, a substrate 101 is provided. The substrate 101 may be any conventional semiconductor substrate such as, for example, a bulk silicon substrate or an active layer of semiconductor material of a silicon-on-insulator (SOI) wafer.

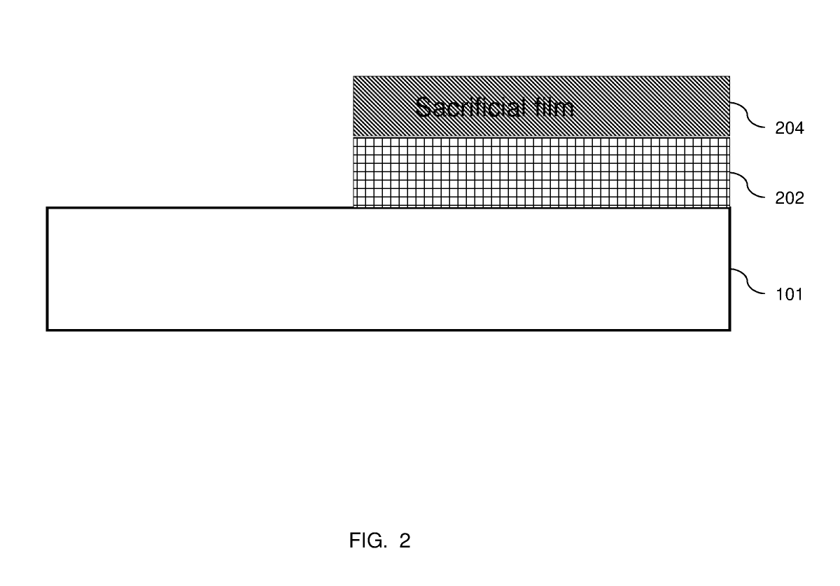

In FIG. 2, a drift dielectric 202 is formed and patterned on the substrate 101. The drift dielectric 202 may be formed of an appropriate dielectric material, such as SiO₂. The dielectrics mentioned herein can, for example, be formed by plasma deposition of SiO₂ or SiO₂ based materials by reacting either tetra-ethyl-ortho-silane (TEOS) or silane with O₂ or activated O₂ (i.e., O₃ or O—). Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance. In some embodiments, the drift dielectric 202 may have a thickness between about 3 nm and about 50 nm.

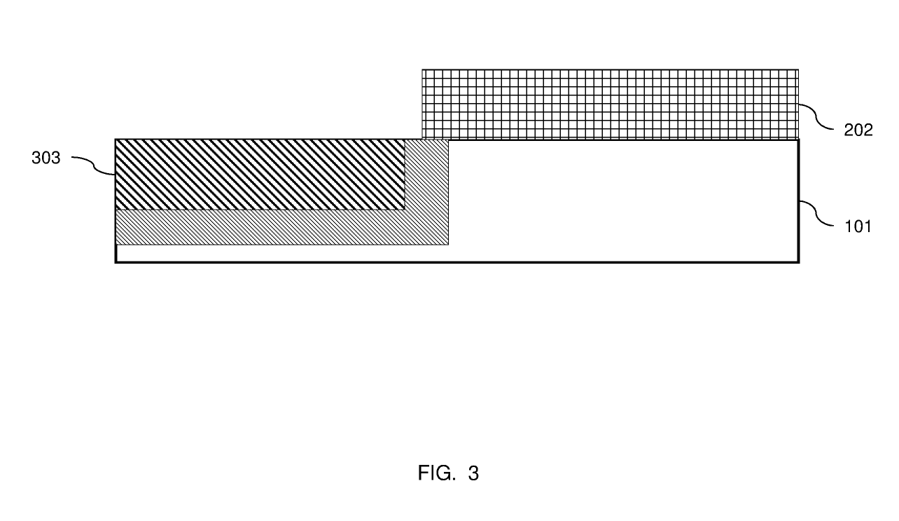

In FIG. 3, a source region 303 is doped to obtain a desired conductivity type. For example, according to structures and methods herein, the source region 303 may be doped with a p-type impurity species, such as boron, to render it p-type in which holes are the majority carriers and dominate the electrical conductivity of the constituent semiconductor material. Alternatively, the source region 303 may be doped with an n-type impurity species, such as arsenic to render it n-type in which electrons are the majority carriers and dominate the electrical conductivity of the semiconductor material. While doping the source region 303, the drift dielectric 202 can be used as a mask, or, a sacrificial film, above the drift dielectric, such as 204 in FIG. 2, can be used as a mask. The sacrificial film 204, if used, could be Si₃N₄ or other film that protects the drift dielectric 202 during lithography. Alternatively, the source region 303 can be formed by using a material removal process (e.g., plasma etching, etc.) to remove unprotected portions of a section of the substrate 101 and a selective epitaxial growth process of appropriately conductive poly may be performed to form the source region 303.

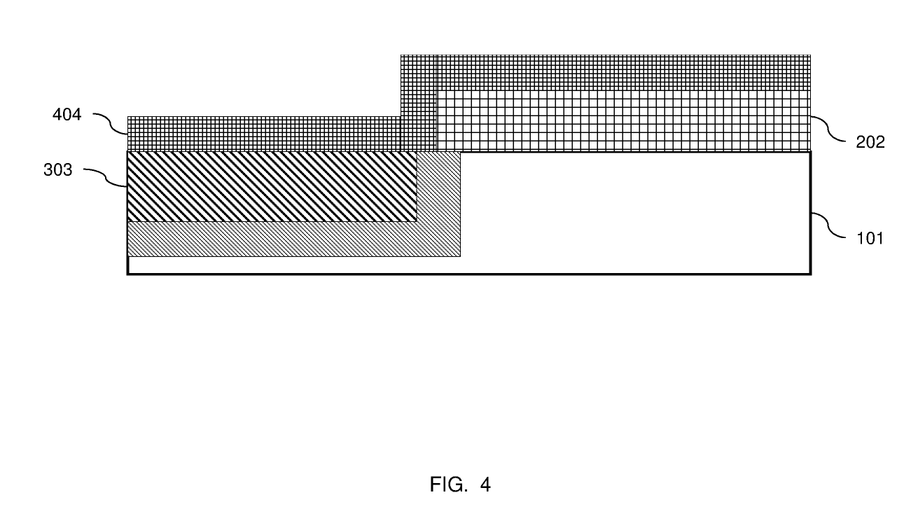

In FIG. 4, a tunnel dielectric 404 is formed over the source region 303 and the drift dielectric 202. In the case where a sacrificial film 204 is employed, it would be removed prior to formation of the tunnel dielectric 404. The tunnel dielectric 404 may be formed of an appropriate dielectric material, such as SiO₂ or HfO, etc. The tunnel dielectric 404 is formed with a thin portion over the source region 303, which enables a low tunnel voltage. The thin portion of the tunnel dielectric 404 may have a thickness between about 0.5 nm and about 1 nm. The source region 303 is self-aligned to the tunnel side of the gate, as described below.

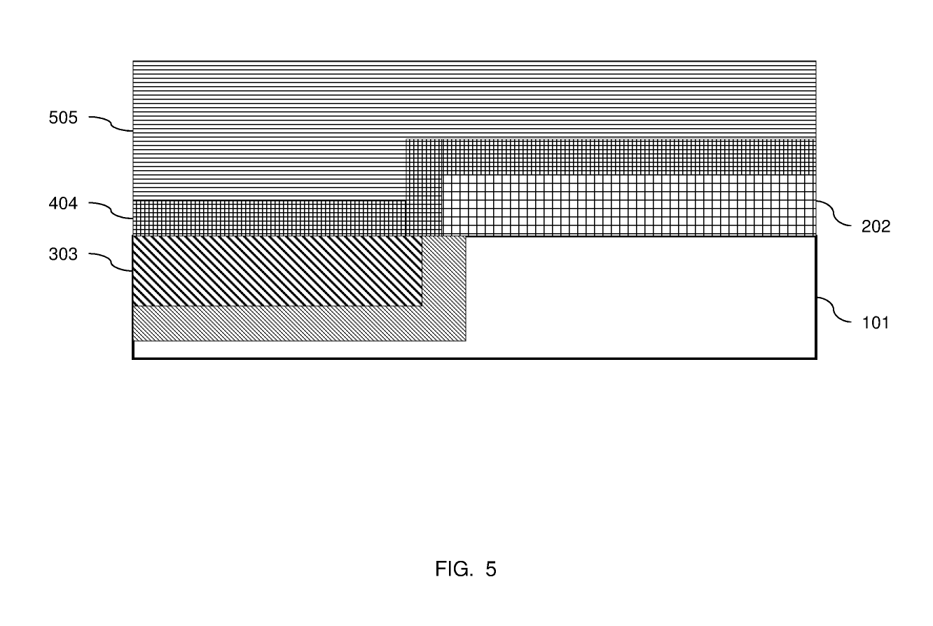

In FIG. 5, a gate electrode 505 is formed over the tunnel dielectric 404. The gate electrode 505 can be deposited on the tunnel dielectric 404 and optionally planarized. The gate electrode 505 is a conductor. The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as TiN, tungsten, hafnium, tantalum, molybdenum, titanium, nickel, aluminum, or copper, or a metal silicide, and alloys of such metals, and may be deposited using physical vapor deposition, chemical vapor deposition, or any other technique known in the art.

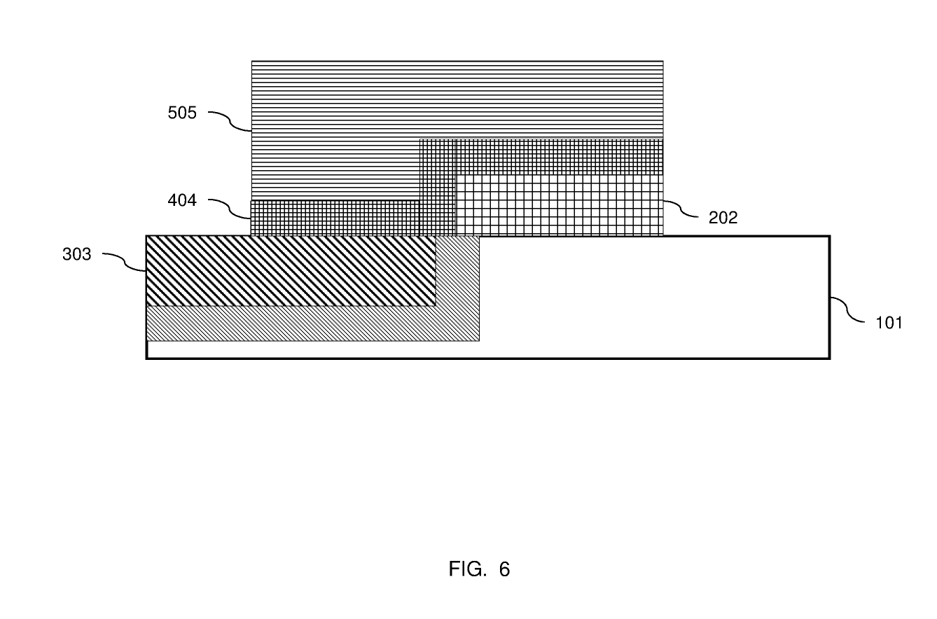

The gate electrode 505 can then be patterned and etched through the tunnel dielectric 404 and drift dielectric 202 to expose a portion of the substrate 101, as shown in FIG. 6. Any appropriate material removal process may be used.

When patterning any material herein, the material to be patterned can be grown or deposited in any known manner and a patterning layer (such as an organic photoresist) can be formed over the material. The patterning layer (resist) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned. A material removal process is then performed (e.g., plasma etching, etc.) to remove the unprotected portions of the material to be patterned. The resist is subsequently removed to leave the underlying material patterned according to the light exposure pattern.

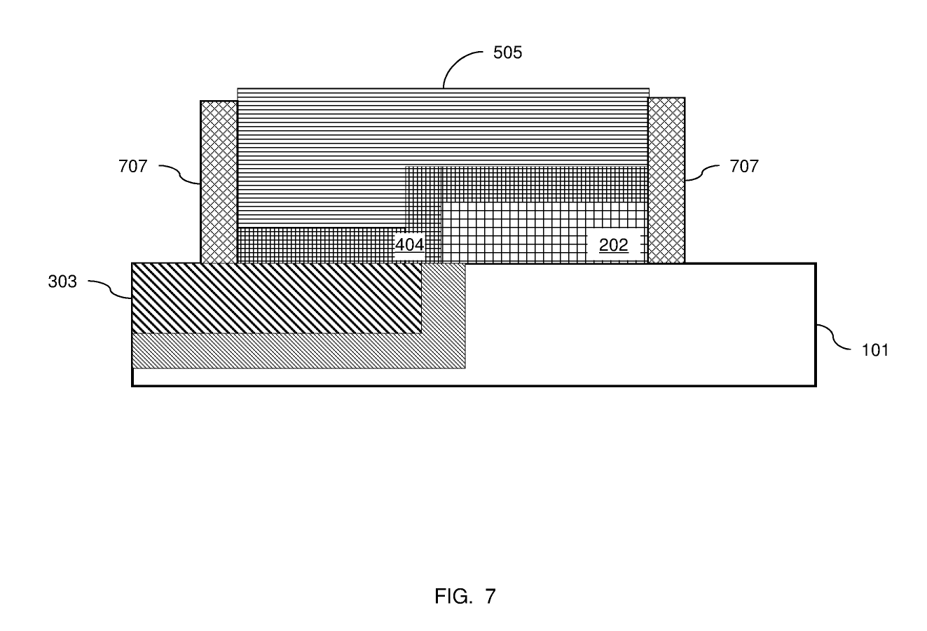

In FIG. 7, spacers 707 are formed at the perimeter of the gate electrode 505. For purposes herein, “spacers” are structures that are well-known to those ordinarily skilled in the art and are generally formed by depositing or growing a conformal insulating layer (and then performing a directional etching process (anisotropic) that etches material from horizontal surfaces at a greater rate than its removes material from vertical surfaces, thereby leaving insulating material along the vertical sidewalls of structures. This material left on the vertical sidewalls is referred to as a spacer. Also, for purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam, and then patterned. Alternatively, the dielectrics herein may be formed from any of the many candidate high dielectric constant (high-k) materials, including but not limited to silicon nitride, silicon oxynitride, a dielectric stack of SiO₂ and Si₃N₄, and metal oxides like tantalum oxide. The thickness of dielectrics herein may vary contingent upon the required device performance.

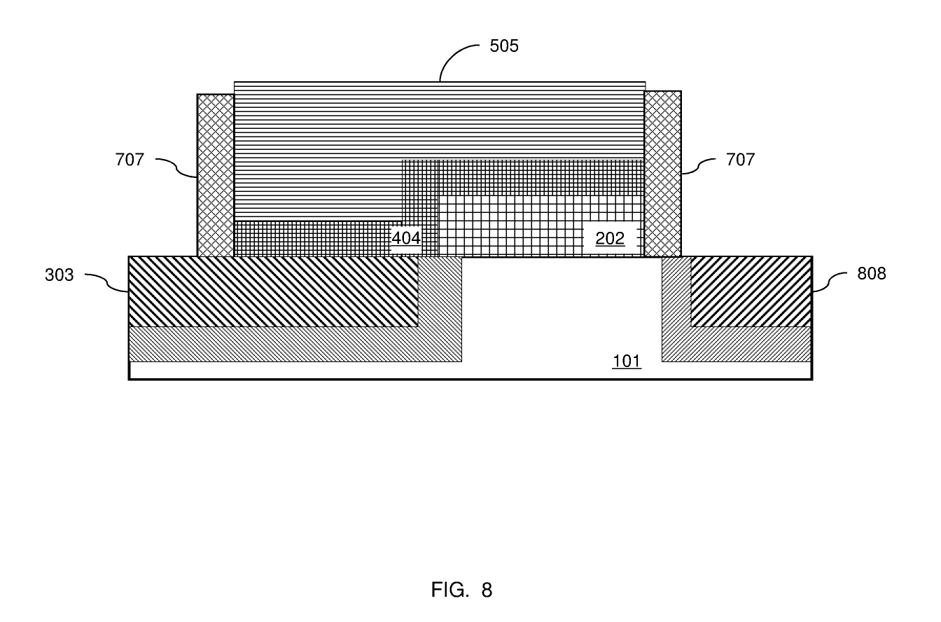

In FIG. 8, a drain region 808 is doped to obtain a desired conductivity type, opposite from the conductivity type of the source region 303. For example, as described above, the source region 303 may be doped with a p-type impurity species, such as boron, to render it p-type. Accordingly, the drain region 808 may be doped with an n-type impurity species, such as arsenic to render it n-type. The drain region 808 can be formed by using a material removal process (e.g., plasma etching, etc.) in which a mask is applied to the structure in order to remove unprotected portions of a section of the substrate 101 and a selective epitaxial growth process of appropriately conductive poly may be performed to form the drain region 808. The drain region 808 is self-aligned to the drift side of the gate. It is understood, by those skilled in the art, that the source region 303 and other non-drain regions of the wafer, can be covered by conventional patterning of a photo-resist or other well-known means while doping of the drain region 808.

A mask can be formed of any suitable material, whether now known or developed in the future, such as a metal or organic or inorganic (Si₃N₄, SiC, SiO₂C (diamond)) hardmask, that has etch resistance greater than the substrate and insulator materials used in the remainder of the structure.

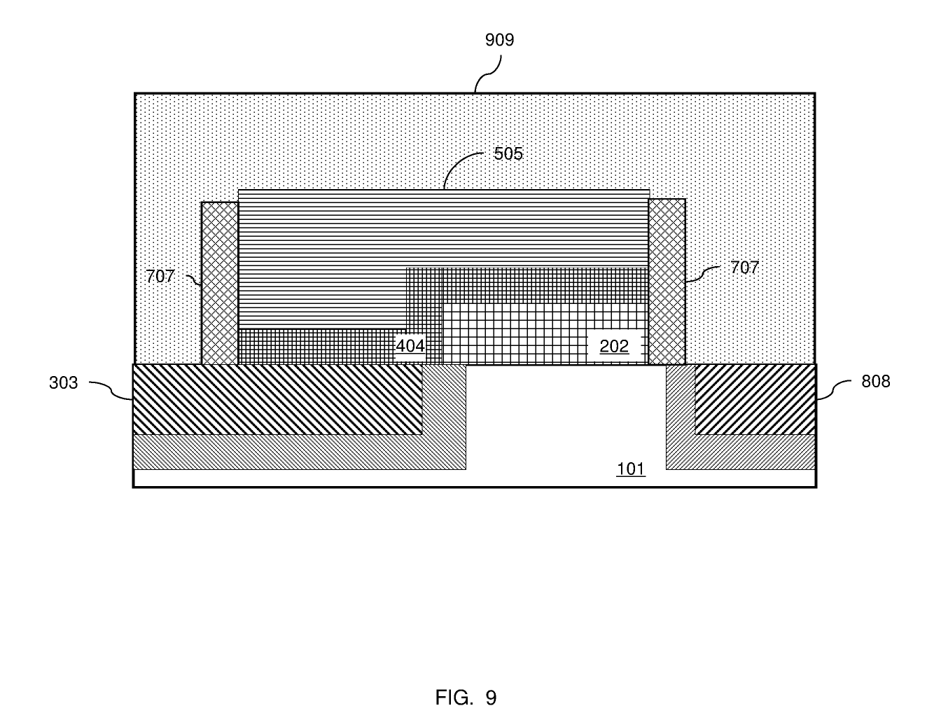

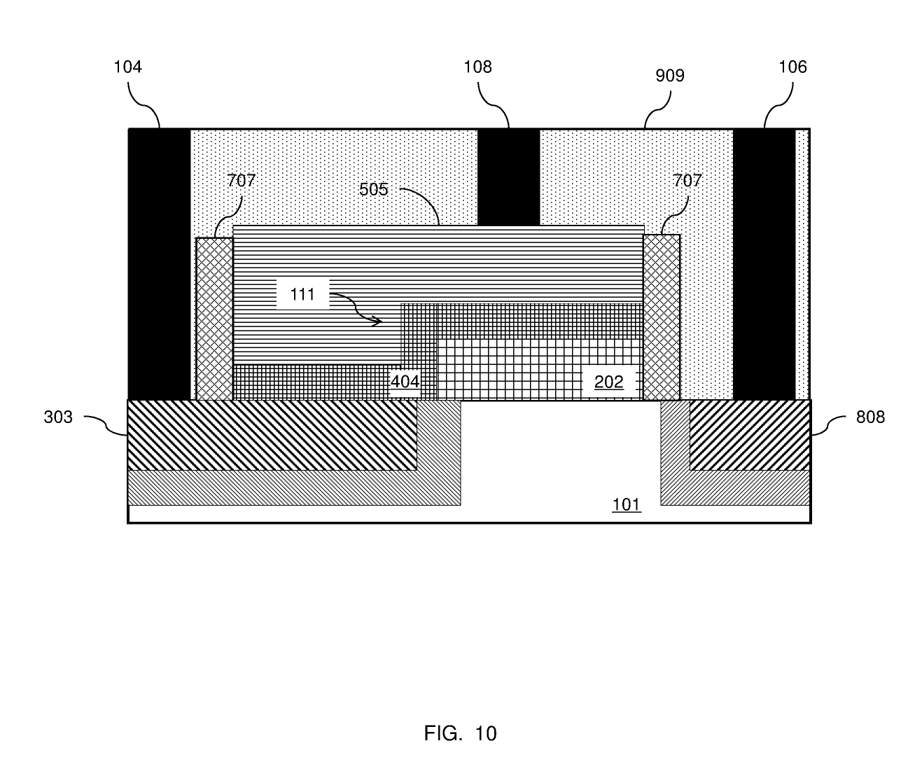

In FIG. 9, an interlevel dielectric 909, such as SiO₂, is formed over the structure. Electrical contacts 104, 106, 108 are created to the source, drain, and gate, respectively, as shown in FIG. 10.

Using a fin architecture with the channel surrounding the source can lead to a large tunneling area. Furthermore, a fin tunnel FET can lead to increased on-current (Ion), which is also compatible with FinFET CMOS flow. A thicker dielectric is provided for the drift dielectric 202 in order to suppress GIDL current, but the alignment of the thin region of the tunnel dielectric 404 over the source region 303 allows the source carriers to efficiently reach the drift region. In other words, the tunnel dielectric 404 and drift dielectric 202 create a channel region 111 between the source region 303 and the drain region 808. For example, when bias on the gate electrode 505 is sufficient to ensure that the conduction band of the intrinsic channel region is aligned with the valence band of the P-type source region 303, tunneling occurs (i.e., electrons from the valence band of the P-type source region tunnel into the conduction band of the intrinsic channel region) and current flows toward the N-type drain region 808.

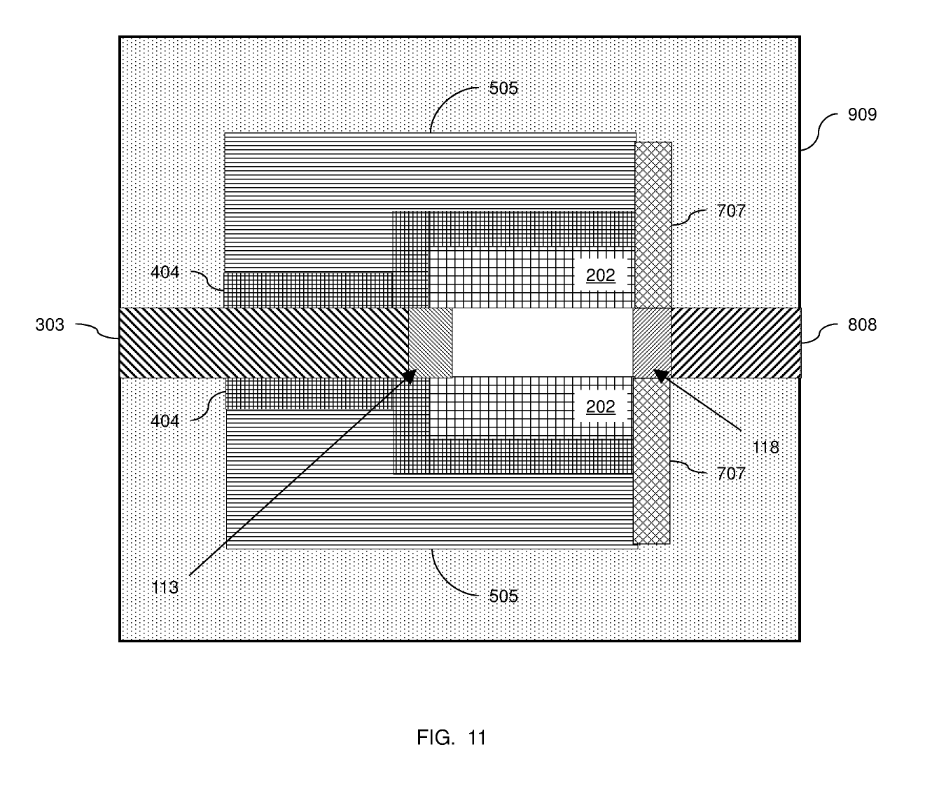

FIG. 11 is a plan view of a cross-section of a tunnel FinFET, according to structures and methods herein. The source region 303 and drain region 808 are formed on a fin, as is known by one of ordinary skill in the art. As described above, the drift dielectric 202 is formed as a relatively thick deposit between the source region 303 and drain region 808. The tunnel dielectric 404 is formed over and around the source region 303 and the drift dielectric 202, and the gate electrode 505 is formed over and around the tunnel dielectric 404. Spacers 707 may be formed at the perimeter of the gate electrode 505. According to structures and methods herein, the source is self-aligned to the tunnel gate, indicated as 113, in FIG. 11. Additionally, the drain is self-aligned to the drift gate, indicated as 118, in FIG. 11.

As described below, silicon wafers may be manufactured in a sequence of steps, each stage placing a pattern of material on the wafer; in this way transistors, contacts, etc., all made of different materials, are laid down. In order for the final device to function correctly, these separate patterns must be aligned correctly—for example contacts, lines, and transistors must all line up. As used herein, “self-aligned” suggests that the contact formation does not require lithographic patterning processes. According to structures and methods herein, a two-part gate dielectric is formed with a thin portion self-aligned to the source enabling low tunnel voltage and a thick portion self-aligned to the drain resulting in low GIDL current. This provides high-density carrier generation and injection of source current to the drift region without the penalties in parasitic leakage current generation.

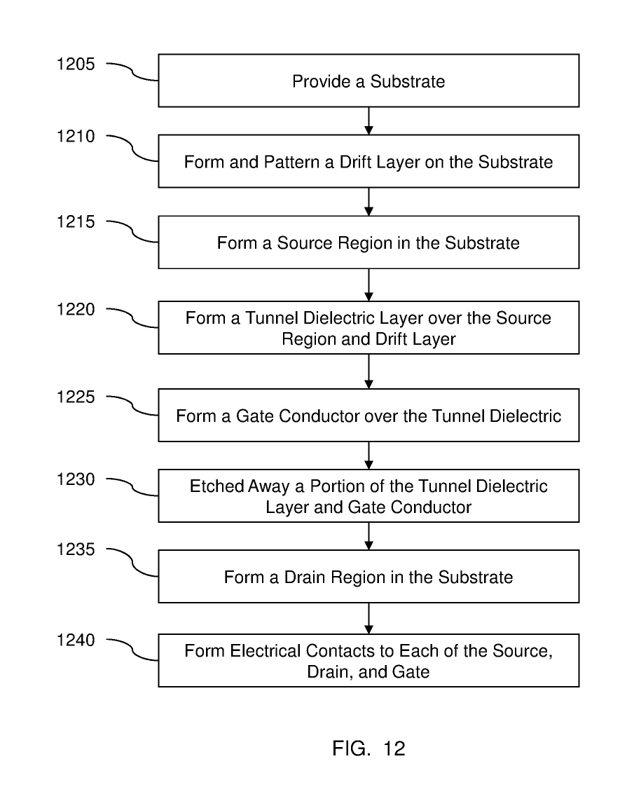

FIG. 12 illustrates a logic flowchart for an exemplary method of manufacturing a tunnel field-effect transistor (TFET), according to structures and methods herein. At 1205, substrate is provided. The substrate may be any conventional semiconductor substrate such as, for example, a bulk silicon substrate or an active layer of semiconductor material of a silicon-on-insulator (SOI) wafer. At 1210, a drift layer is formed and patterned on the substrate. The drift dielectric may be formed of an appropriate dielectric material, such as SiO₂. At 1215, a first portion of the substrate is doped to form a source region in the substrate. According to structures and methods herein, the source region may be doped with a p-type impurity species, such as boron, to render it p-type in which holes are the majority carriers and dominate the electrical conductivity of the constituent semiconductor material. Alternatively, the source region may be doped with an n-type impurity species, such as arsenic to render it n-type in which electrons are the majority carriers and dominate the electrical conductivity of the semiconductor material. At 1220, a tunnel dielectric layer is formed over the source region and drift layer. The tunnel dielectric may be formed of an appropriate dielectric material, such as SiO₂ or HfO, etc. The tunnel dielectric is formed with a thin portion over the source region, which enables a low tunnel voltage. The source region is self-aligned to the tunnel side of the gate. At 1225, a gate electrode is formed over the tunnel dielectric. The gate electrode can be formed of any conductive material, such as polycrystalline silicon (polysilicon), amorphous silicon, a combination of amorphous silicon and polysilicon, and polysilicon-germanium, rendered conductive by the presence of a suitable dopant. At 1230, a portion of the tunnel dielectric layer and gate electrode is etched away down to the substrate. Any appropriate material removal process can be used. At 1235, a second portion of the substrate is doped to form a drain region in the substrate. The drain region has conductivity that is opposite from the source region. At 1240, electrical contacts are formed to each of the source, drain, and gate. The electrical contacts may be one or more metals, such as tungsten, hafnium, tantalum, molybdenum, titanium, nickel, aluminum, or copper, or a metal silicide, and alloys of such metals.

With its unique and novel features, the structures and methods herein teach an exemplary tunnel field-effect transistor (TFET). The TFET includes a gate electrode, a source region, and a drain region. The source region and drain region are of opposite conductivity types. A dielectric layer separates the gate electrode from the source region and drain region. The dielectric layer provides a channel between the source region and the drain region. The channel is made of a tunnel gate dielectric and a drift dielectric. The tunnel gate dielectric is relatively thin between the source region and the gate electrode and the drift dielectric is relatively thick between the gate electrode and the drain region.

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Aspects of the present disclosure are described herein with reference to flowchart illustrations and/or block diagrams of methods, apparatus (systems), and computer program products according to embodiments herein. It will be understood that each block of the flowchart illustrations and/or two-dimensional block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

It should be understood that the terminology used herein is for the purpose of describing particular embodiments only and is not intended to be limiting of this disclosure. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The corresponding structures, materials, acts, and equivalents of all means or step plus function elements in the claims below are intended to include any structure, material, or act for performing the function in combination with other claimed elements as specifically claimed. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Disclosed above are tunnel FinFETs (or TFETs) with a self-aligned gate that allows for high fields at the junction edge and low gate-induced drain leakage (GIDL) current. Specifically, the disclosed TFETs can incorporate a relatively thin dielectric between the source-tunnel region and the gate to generate channel carriers by tunneling and a thicker dielectric for the drift region in which the alignment of the thin region allows the source carriers to efficiently reach the drift region. The TFET devices include a gate electrode, a source region having a first conductivity type, a drain region having a second conductivity type opposite from the first conductivity type, and a dielectric layer separating the gate electrode from the source region and the drain region. The dielectric layer provides a channel region between the source region and the drain region. The channel region includes the tunnel region having a relatively thin dielectric between the source region and the gate electrode and a relatively thick drift dielectric between the gate electrode and the drain region. Specifically, a two-part gate dielectric is formed with a thin portion self-aligned to the source, enabling low tunnel voltage, and a thick portion self-aligned to the drain, enabling low current resulting from gate-induced drain leakage (GIDL).

What is claimed is:

1. A method, comprising:
forming a drift layer over a substrate;
doping a first portion of the substrate to form a source region in the substrate;
forming a tunnel dielectric layer over the source region and drift layer;
forming a gate electrode over the tunnel dielectric layer;
etching away a portion of the tunnel dielectric layer and gate electrode down to the substrate; and
doping a second portion of the substrate to form a drain region in the substrate.

2. The method according to claim 1, the drift layer having a thickness between about 3 nm and about 50 nm.

3. The method according to claim 1, the tunnel dielectric layer having a thickness smaller than about 1 nm.

4. The method according to claim 1, the source region and drain region being doped for opposite conductivity types.

5. The method according to claim 1, further comprising:
after etching away a portion of the tunnel dielectric layer and gate electrode down to the substrate, forming a spacer on the perimeter of the gate electrode.

6. The method according to claim 1, further comprising:
depositing an interlevel dielectric over the source region, gate electrode, and drain region.

7. The method according to claim 1, further comprising:
forming electrical contacts connected to each of the source region, drain region, and gate electrode.

8. A method of manufacturing a tunnel field-effect transistor (TFET), the method comprising:
providing a substrate;
forming a first dielectric layer on the substrate;
applying a first pattern on the first dielectric layer and performing first lithographic processes to remove a portion of the first dielectric layer;
forming a source region in a first portion of the substrate, the first portion being an area not covered by the first dielectric layer;
forming a second dielectric layer over the source region and the first dielectric layer;
depositing a gate electrode material on the second dielectric layer;
applying a second pattern on the gate electrode material and performing second lithographic processes to remove portions of the gate electrode material, the first dielectric layer and the second dielectric layer, exposing at least part of the first portion of the substrate with the source region and a second portion of the substrate; and
forming a drain region in the second portion of the substrate.

9. The method according to claim 8, wherein forming the source region comprises doping the first portion of the substrate with a first type of doping material.

10. The method according to claim 8, wherein forming the drain region comprises doping the second portion of the substrate with a second type of doping material.

11. The method according to claim 8, wherein the source region and drain region are doped for opposite conductivity types.

12. The method according to claim 8, further comprising:
forming a spacer around the gate electrode material.

13. The method according to claim 8, further comprising:
depositing an interlevel dielectric over the source region, the gate electrode material, and the drain region.

14. The method according to claim 13, further comprising:
forming electrical contacts connected to each of the source region, the drain region, and the gate electrode material.

15. The method according to claim 8, wherein the first dielectric layer has a thickness between about 3 nm and about 50 nm.

16. The method according to claim 8, wherein the second dielectric layer has a thickness smaller than about 1 nm.

17. A method of manufacturing a tunnel field-effect transistor (TFET), the method comprising:
providing a substrate;
forming a drift layer on the substrate;
applying a first pattern on the drift layer and performing first lithographic processes to remove a portion of the drift layer;
forming a source region in a first portion of the substrate, the first portion being an area not covered by the drift layer;
forming a tunnel dielectric layer over the source region and the drift layer;
depositing a gate electrode material on the tunnel dielectric layer;
applying a second pattern on the gate electrode material and performing second lithographic processes to remove portions of the gate electrode material, the drift layer and the tunnel dielectric layer, forming a gate electrode and exposing at least part of the first portion of the substrate with the source region and a second portion of the substrate;
forming a spacer around the gate electrode; and
forming a drain region in the second portion of the substrate.

18. The method according to claim 17, wherein forming the source region comprises doping the first portion of the substrate with a first type of doping material, and
wherein forming the drain region comprises doping the second portion of the substrate with a second type of doping material, the first type of doping material being different from the second type of doping material.

19. The method according to claim 17, further comprising:
depositing an interlevel dielectric layer over the source region, the gate electrode, and the drain region.

20. The method according to claim 18, further comprising:
forming electrical contacts connected to each of the source region, the drain region, and the gate electrode, through the interlevel dielectric layer.
